(19) United States
(12) Patent Application Publication
(10) Pub. No.: US 2012/0241848 A1
(43) Pub. Date: Sep. 27, 2012

(54) SEMICONDUCTOR ELEMENT AND METHOD OF MANUFACTURING SEMICONDUCTOR ELEMENT

(75) Inventor: Takeshi UCHIHARA, Saitama-ken (JP)

(73) Assignee: KABUSHIKI KAISHA TOSHIBA, Tokyo (JP)

(21) Appl. No.: 13/234,045

(22) Filed: Sep. 15, 2011

(30) Foreign Application Priority Data
Mar. 25, 2011 (JP) 2011-067087

(51) Int. Cl. H01L 29/78; H01L 21/336

(52) U.S. Cl. 257/330; 438/270; 257/E29.262; 257/E21.41

(57) ABSTRACT

A semiconductor element includes a drain layer, a drift region selectively provided in the drain layer, a base region selectively provided in the drift region, a source region selectively provided in the base region, first and/or second metal layers selectively provided in at least one of the source region and the drain layer from the front surface to the inside of at least one of the source region and the drain layer, a gate electrode in a trench shape extending in a direction substantially parallel to the front surface of the drain layer from a part of the source region through the base region adjacent to at least the part of the source region to a part of the drift region, a source electrode connected to the first metal layer, and a drain electrode connected to the drain layer or the second metal layer.

### CROSS-REFERENCE TO RELATED APPLICATION

This application is based upon and claims the benefit of priority from the prior Japanese Patent Application No. 2011-067087, filed on Mar. 25, 2011; the entire contents of which are incorporated herein by reference.

### FIELD

Embodiments described herein relate generally to a semiconductor element and a method of manufacturing the semiconductor element.

### BACKGROUND

There is a need to reduce the on-resistance in a power semiconductor element. To meet the need, a three-dimensional semiconductor element is proposed recently in which the channel region is formed not only on the front surface of the semiconductor substrate but also in the vertical direction of the semiconductor substrate. In the three-dimensional semiconductor element, a source region, a base region and a drain region are formed to extend in a direction substantially vertical to the front surface of the semiconductor substrate and a gate electrode in a trench shape is provided. By forming the semiconductor element in the above-described structure, the channel region is formed in a direction substantially parallel to the front surface of the semiconductor substrate and the channel region is formed also in the direction substantially vertical to the front surface of the semiconductor substrate. As a result, the channel density improves to reduce the on-resistance of the semiconductor element.

### BRIEF DESCRIPTION OF THE DRAWINGS

FIG. 1 is a schematic perspective view of a principal part of a semiconductor device according to a first embodiment.

FIGS. 2A and 2B are schematic views of a principal part of a semiconductor element according to the first embodiment.

FIG. 3 is a schematic plan view of the principal part of the semiconductor device according to the first embodiment.

FIGS. 4A to 4I are explanatory views of the manufacturing process of the semiconductor element according to the first embodiment.

FIG. 5 is a schematic sectional view of a principal part of a semiconductor device according to another example of the first embodiment.

FIGS. 6A and 6B are schematic views of a principal part of a semiconductor element according to a second embodiment.

FIGS. 7A to 7C are explanatory views of the manufacturing process of the semiconductor element according to the second embodiment.

FIG. 8 is a schematic sectional view of a principal part of a semiconductor device according to another example of the second embodiment.

FIGS. 9A and 9B are schematic views of a principal part of a semiconductor element according to a third embodiment.

FIGS. 10A to 10C are explanatory views of the manufacturing process of the semiconductor element according to the third embodiment.

FIG. 11 is a schematic sectional view of a principal part of a semiconductor device according to another example of the third embodiment.

FIG. 12 is a schematic view of a principal part of a semiconductor element according to a fourth embodiment.

FIG. 13 is a schematic sectional view of a principal part of a semiconductor element according to another example of the fourth embodiment.

FIGS. 14A and 14B are schematic views of a principal part of a semiconductor element according to a fifth embodiment.

FIGS. 15A to 15F are explanatory views of the manufacturing process of the semiconductor element according to the fifth embodiment.

FIG. 16 is a graph representing the relation between the distance L and the withstand voltage of the semiconductor element.

FIGS. 17, 18A and 18B are schematic views of principal parts of semiconductor elements according to other examples of the fifth embodiment.

### DETAILED DESCRIPTION

A semiconductor element according to an embodiment includes: a drain layer having a front surface and a rear surface; a drift region selectively provided in the drain layer from the front surface to an inside of the drain layer; a base region selectively provided in the drift region from a front surface to an inside of the drift region; a source region selectively provided in the base region from a front surface to an inside of the base region; first and/or second metal layers selectively provided in at least one of the source region and the drain layer from the front surface to the inside of at least one of the source region and the drain layer; a gate electrode in a trench shape extending in a direction substantially parallel to the front surface of the drain layer from a part of the source region through the base region adjacent to at least the part of the source region to a part of the drift region; a source electrode connected to the first metal layer; and a drain electrode connected to the drain layer or the second metal layer.

Hereinafter, embodiments will be described with reference to the drawings. The surface where a later-described source electrode is formed is defined as a front surface and the surface opposite the front surface is defined as a rear surface.

### First Embodiment

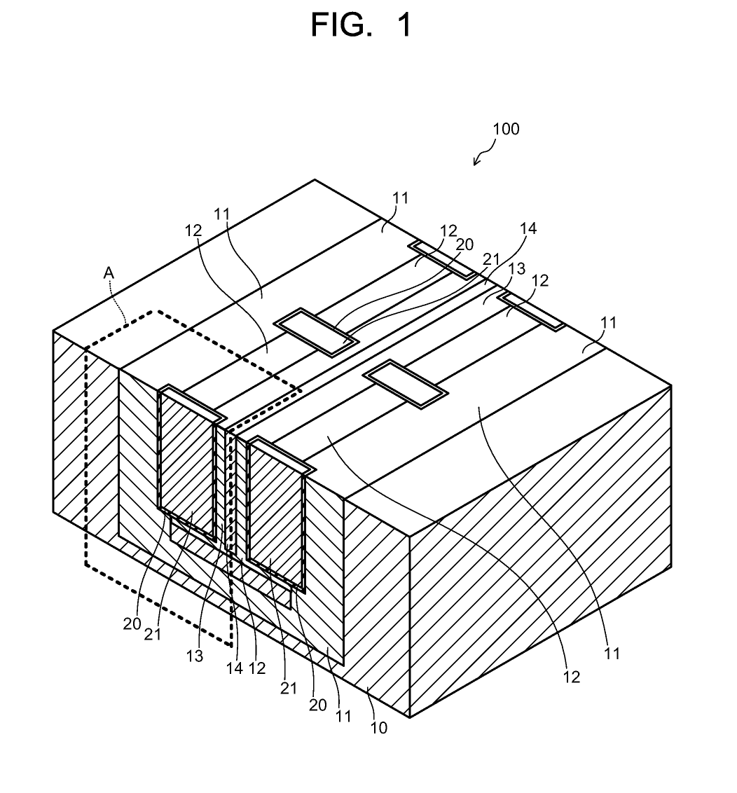

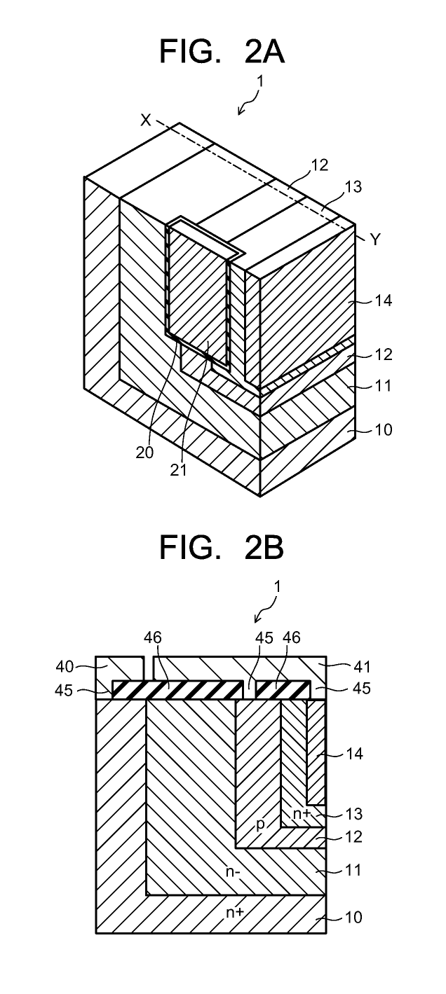

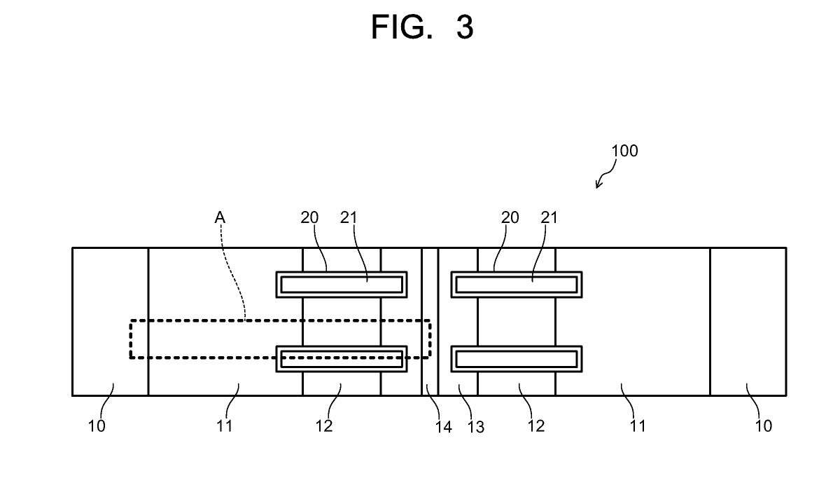

FIG. 1 is a schematic perspective view of a principal part of a semiconductor device 100 according to a first embodiment. The semiconductor device 100 according to the first embodiment includes a plurality of later-described semiconductor elements 1. FIGS. 2A and 2B are schematic views of a principal part of the semiconductor element 1. FIG. 2A is a schematic perspective view of the principal part of the semiconductor element 1. FIG. 2B is a schematic sectional view at an X-Y position in FIG. 2A. FIG. 3 is a schematic plan view of the principal part of the semiconductor device 100 according to the first embodiment. In FIG. 1, FIG. 2A and FIG. 3, illustration of drain electrode 40 and source electrode 41 are omitted.

### (Structure of Semiconductor Element 1)

The semiconductor element 1 is a three-dimensional MOSFET (Metal-Oxide-Semiconductor Field-Effect Transistor). As illustrated in FIGS. 2A and 2B, the semiconductor element 1 includes an n⁺-type (first conduction type) drain layer 10, a drift region 11, a p-type (second conduction type) base region 12, an n-type (first conduction type) source region 13, a metal layer 14, a gate insulating film 20, a gate electrode 21, the drain electrode 40, the source electrode 41, via electrodes 45, and an interlayer insulating film 46.

The drift region 11 is selectively formed from the front surface to the inside of the drain layer 10. The concentration of the n-type impurity contained in the drain layer 10 is higher than the concentration of the n-type impurity contained in the drift region 11. The p-type base region 12 is selectively formed from the front surface to the inside of the drift region 11.

The source region 13 is selectively formed from the front surface to the inside of the base region 12. The metal layer 14 is selectively formed from the front surface to the inside of the source region 13. The gate electrode 21 is selectively formed from the front surfaces to the insides of a part of the source region 13 to a part of the drift region 11 across the base region 12, via the gate insulating film 20. The gate electrode 21 is in a trench shape and is formed in a direction substantially vertical to the front surface of the drain layer 10.

The gate electrode 21 extends from a part of the source region 13 through the base region 12 adjacent to the source region 13 to a part of the drift region 11. The lower end of the gate insulating film 20 is located between the lower end of the base region 12 and the lower end of the source region 13.

The drain electrode 40 is connected to the drain layer 10 via the via electrode 45. The source electrode 41 is connected to the base region 12 and the metal layer 14 in the source region 13 via the via electrodes 45. The interlayer insulating film 46 intervenes between the drain electrode 40 and the drain layer 10. The interlayer insulating film 46 intervenes between the source electrode 41 and the drift region 11, the base region 12 and the source region 13.

As illustrated in FIG. 3, the arrangement of the drift region 11, the base region 12 and the gate electrode 21 on the front surface of the semiconductor device 100 is line symmetric about the source region 13 as a symmetrical axis. The unit illustrated in FIG. 3 is periodically arranged in a direction parallel to the front surface of the drain layer 10 to construct the semiconductor device 100.

The main component of the drain layer 10, the drift region 11, the base region 12 and the source region 13 is semiconductor, for example, silicon (Si) or the like. The material of the metal layer 14 is metal with a resistance lower than that of the source region 13, for example, tungsten (W). The material of the gate electrode 21 is, for example, poly-silicon (Poly-Si). The material of the gate insulating film 20, the interlayer insulating film 46 and the insulating layer 50 is, for example, silicon oxide (SiO₂). The material of the drain electrode 40 and the source electrode 41 is, for example, copper (Cu), aluminum (Al).

### (Manufacturing Process of Semiconductor Element 1)

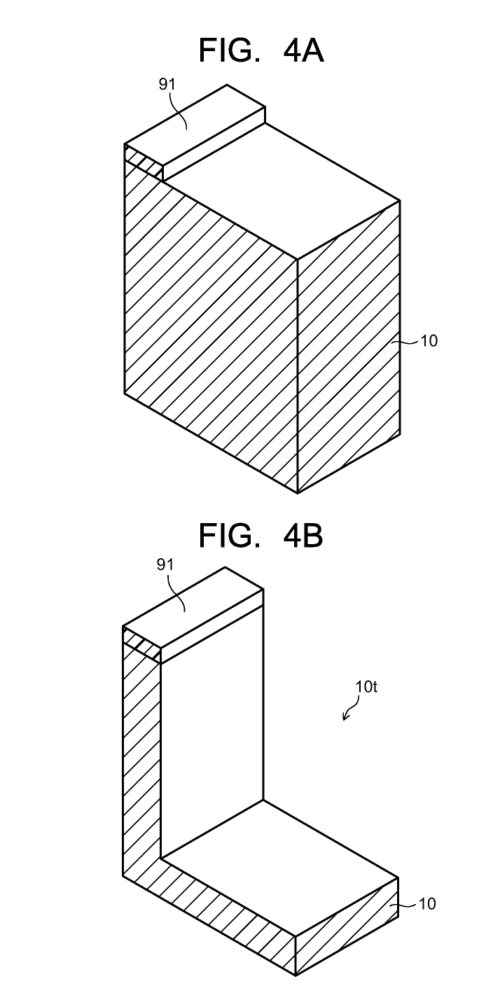

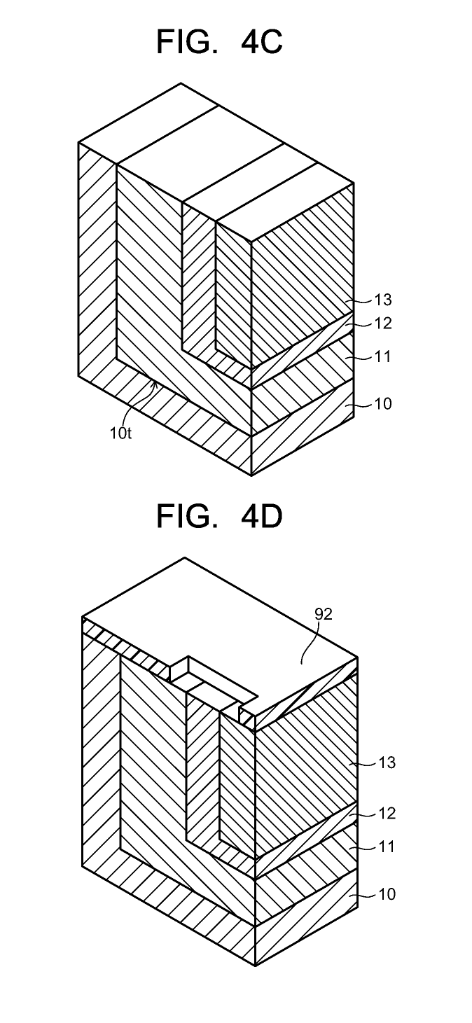

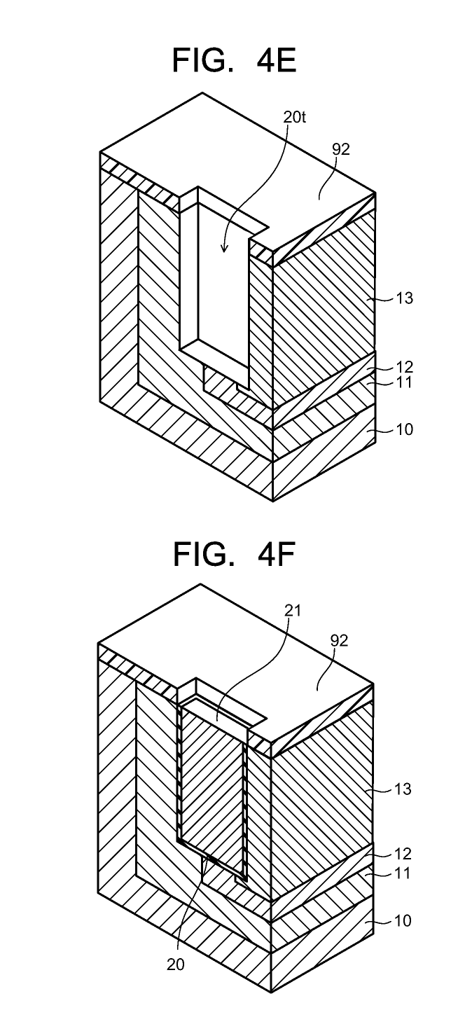

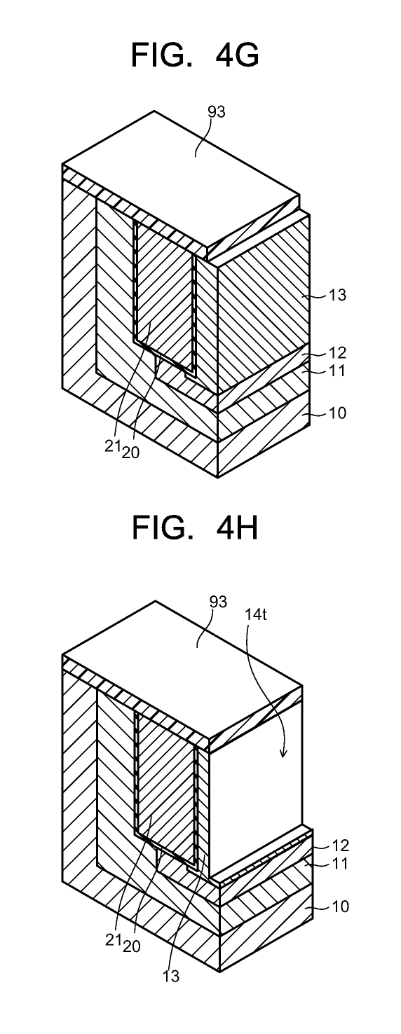

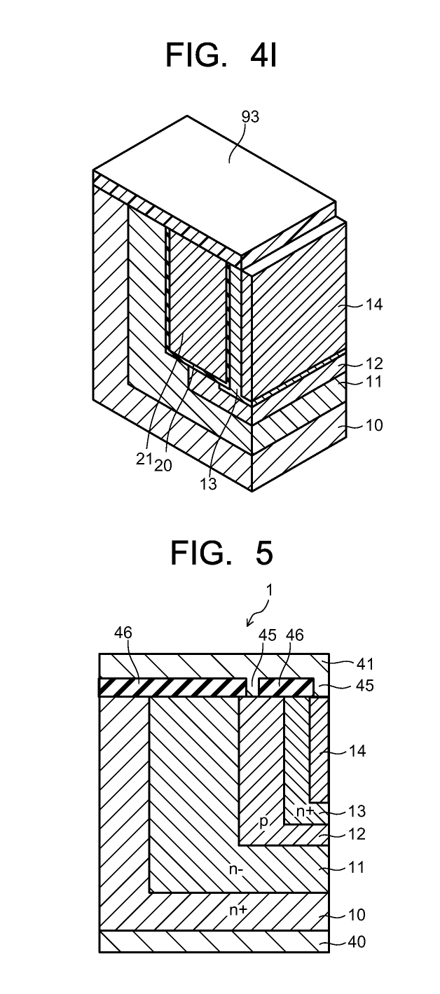

FIGS. 4A to 4I are explanatory views of the manufacturing process of the semiconductor element 1 according to the first embodiment. Hereinafter, the manufacturing process of the semiconductor element 1 will be described with reference to FIGS. 4A to 4I.

### (Mask Forming Step: see FIG. 4A)

The drain layer 10 that is a semiconductor substrate (semiconductor wafer) is prepared. The impurity concentration of the drain layer 10 is, for example, 1×10¹⁸ atoms/cm³ or higher. Subsequently, a mask 91 is selectively formed so that a part of the front surface of drain layer 10 is exposed. The material of the mask 91 is, for example, silicon oxide (SiO₂).

### (Etching Step: see FIG. 4B)

As illustrated in FIG. 4B, the drain layer 10 exposed from the mask 91 is selectively etched. As a result, a trench 10t is formed from the front surface to the inside of the drain layer 10.

### (Drift Region 11 Forming Step: see FIG. 4C)

Inside the trench 10t, the n-type drift region 11 is formed by the epitaxial growth method. As a result, the drift region 11 is formed from the front surface to the inside of the drain layer 10. The impurity concentration of the drift region 11 is, for example, 1×10¹² atoms/cm³ to 1×10¹³ atoms/cm³.

The formation of the drift region 11 is interrupted in the middle, and the p-type base region 12 is formed in the trench 10t left in the drift region 11 using the epitaxial growth method. As a result, the base region 12 is formed from the front surface to the inside of the drift region 11.

The formation of the base region 12 is interrupted in the middle, and the n⁺-type source region 13 is formed in the trench 10t left in the base region 12 by the epitaxial growth method. As a result, the source region 13 is selectively formed from the front surface to the inside of the base region 12.

CMP (Chemical Mechanical Polishing) is employed to polish the front surfaces of the drift region 11, the base region 12 and the source region 13 to flatten the front surfaces of the drift region 11, the base region 12 and the source region 13. The mask 91 is removed by the CMP.

### (Mask Forming Step: see FIG. 4D)

As illustrated in FIG. 4D, a mask 92 is selectively formed so that parts of the front surfaces of the drift region 11, the base region 12 and the source region 13 are exposed. The material of the mask 92 is, for example, silicon oxide (SiO₂).

### (Trench Forming Step: see FIG. 4E)

As illustrated in FIG. 4E, the parts of the drift region 11, the base region 12 and the source region 13 opened in the mask 92 are selectively etched. As a result, a trench 20t is formed in the parts of the drift region 11, the base region 12 and the source region 13.

### (Gate Forming Step: see FIG. 4F)

The inside of the trench 20t is exposed to an oxidizing atmosphere under a high temperature. As a result, the gate insulating film 20 is formed at the side surface and the bottom surface of the trench 20t. Then, the gate electrode 21 is formed in the trench 20t by CVD (Chemical Vapor Deposition) via the gate insulating film 20. As a result, the gate electrode 21 in the trench shape is selectively formed from the front surfaces to the insides of parts of the source region 13 to the drift region 11 across the base region 12. After the formation of the gate electrode 21, the mask 92 is removed.

### (Mask Forming Step: see FIG. 4G)

A mask 93 is selectively formed so that a part of the front surface of the source region 13 is exposed. The material of the mask 93 is, for example, silicon oxide (SiO₂).

### (Trench Forming Step: see FIG. 4H)

As illustrated in FIG. 4H, the part of the source region 13 opened in the mask 93 is selectively etched. As a result, a trench 14t is formed in the part of the source region 13.

### (Metal Layer Forming Step: see FIG. 4I)

In the trench 14t, the metal layer 14 is formed. As a result, the metal layer 14 in the trench shape is selectively formed from the front surface to the inside of the part of the source region 13. The metal layer 14 is preferably formed using W-CVD (tungsten CVD) because it provides excellent embedding property and requires no barrier metal and so on. However, the formation of the metal layer 14 is not limited to W-CVD. Al-CVD or PVD may be used, for instance, as long as the embedding property is ensured. After the formation of the metal layer 14, the mask 93 is removed.

As illustrated in FIG. 2B, the interlayer insulating film 46 is formed on the drain layer 10, the drift region 11, the base region 12, the source region 13 and the metal layer 14. Then, a metal material such as tungsten (W) or the like is filled in via holes formed in the interlayer insulating film 46 to form the via electrodes 45. Thereafter, the drain electrode 40 and the source electrode 41 are formed on the interlayer insulating film 46 and the via electrodes 45.

In the semiconductor element 1 according to the first embodiment, the metal layer 14 is selectively formed from the front surface to the inside of the source region 13 and the source electrode 41 is connected to the metal layer 14 as described above. By providing the metal layer 14, the electric resistance (source resistance) of the source region 13 can be reduced. As a result, the on-resistance of the semiconductor element 1 can be effectively reduced.

In the manufacturing process of the semiconductor element 1 described referring to FIGS. 4A to 4I, the metal layer 14 is formed after the gate electrode 21 is formed. However, the gate electrode 21 may be formed after the metal layer 14 is formed. The drain electrode 40 may be formed on the rear surface side of the semiconductor element 1 as illustrated in FIG. 5.

### Second Embodiment

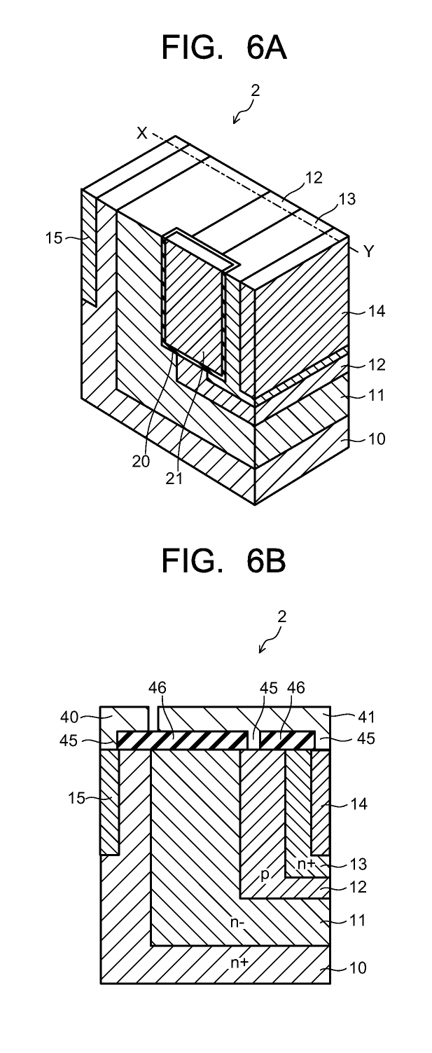

FIGS. 6A and 6B are schematic views of a principal part of a semiconductor element 2 according to a second embodiment. FIG. 6A is a schematic perspective view of the principal part of the semiconductor element 2. FIG. 6B is a schematic sectional view at an X-Y position in FIG. 6A. Hereinafter, the structure of the semiconductor element 2 according to the second embodiment will be described with reference to FIGS. 6A and 6B. The same configurations as those described in FIGS. 2A to 4I are given the same numerals and overlapping description will be omitted. In FIG. 6A, illustration of a drain electrode 40 and a source electrode 41 are omitted.

### (Structure of Semiconductor Element 2)

The semiconductor element 2 is a three-dimensional MOSFET. The semiconductor element 2 includes a metal layer 15 selectively formed from the front surface to the inside of the drain layer 10 as illustrated in FIGS. 6A and 6B. By providing the metal layer 15, the electric resistance (drain resistance) of the drain layer 10 can be reduced. As a result, the on-resistance of the semiconductor element 2 can be further reduced. The other structure is the same as that of the semiconductor element 1 described referring to FIG. 3.

### (Manufacturing Process of Semiconductor Element 2)

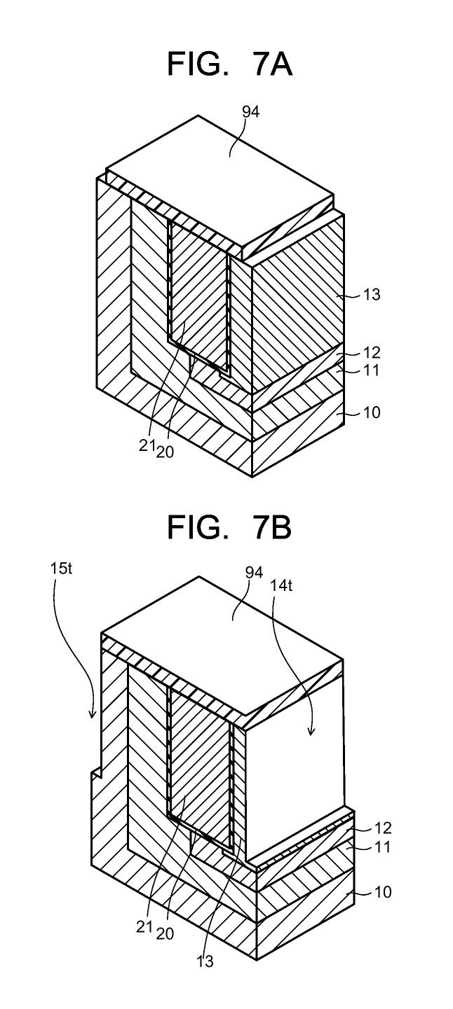

FIGS. 7A to 7C are explanatory views of the manufacturing process of the semiconductor element 2 according to the second embodiment. Hereinafter, the manufacturing process of the semiconductor element 2 will be described with reference to FIGS. 7A to 7C. The manufacturing process is the same as the manufacturing process of the semiconductor element 1 until the step of forming the gate electrode 21 described referring to FIG. 4F. Therefore, the manufacturing process after the gate electrode 21 is formed will be described in this second embodiment. The same configurations as those described in FIGS. 2A to 4I are given the same numerals and overlapping description will be omitted.

### (Mask Forming Step: see FIG. 7A)

As illustrated in FIG. 7A, a mask 94 is selectively formed so that parts of the front surfaces of a source region 13 and a drain layer 10 are exposed. The material of the mask 94 is, for example, silicon oxide (SiO₂).

### (Trench Forming Step: see FIG. 7B)

As illustrated in FIG. 7B, parts of the source region 13 and the drain layer 10 opened in the mask 94 are selectively etched. As a result, a trench 14t and a trench 15t are formed in the part of the source region 13 and the part of the drain layer 10 respectively.

### (Metal Layer Forming Step: see FIG. 7C)

In the trench 14t and the trench 15t, a metal layer 14 and a metal layer 15 are formed. As a result, the metal layer 14 and the metal layer 15 in the trench shape are selectively formed from the front surfaces to the insides of parts of the source region 13 and the drain layer 10. The metal layer 14 and the metal layer 15 are preferably formed using W-CVD (tungsten CVD) because it provides excellent embedding property and requires no barrier metal and so on. However, the formation of the metal layer 14 and the metal layer 15 is not limited to W-CVD. Al-CVD or PVD may be used, for instance, as long as the embedding property is ensured. After the formation of the metal layer 14 and the metal layer 15, the mask 94 is removed.

As illustrated in FIG. 6B, an interlayer insulating film 46 is formed on the drain layer 10, the drift region 11, the base region 12, the source region 13, the metal layer 14 and the metal layer 15. Then, a metal material such as tungsten (W) or the like is filled in via holes formed in the interlayer insulating film 46 to form via electrodes 45. Thereafter, the drain electrode 40 and the source electrode 41 are formed on the interlayer insulating film 46 and the via electrodes 45.

In the semiconductor element 2 according to the second embodiment, the metal layer 14 is selectively formed from the front surface to the inside of the source region 13 and the source electrode 41 is connected to the metal layer 14 as described above. Further, the metal layer 15 is selectively formed from the front surface to the inside of the drain layer 10 and the drain electrode 40 is connected to the metal layer 15. By providing the metal layer 15, the electric resistance (drain resistance) of the drain layer 10 can be reduced. As a result, the on-resistance of the semiconductor element 2 can be further reduced.

Since the metal layer 14 in the source region 13 and the metal layer 15 in the drain layer 10 are formed concurrently, namely, in the same step, the number of manufacturing process steps of the semiconductor element 2 can be reduced as compared to the case that the metal layer 14 and the metal layer 15 are formed in separate steps. The other effects are the same as those of the semiconductor element 1 according to the first embodiment.

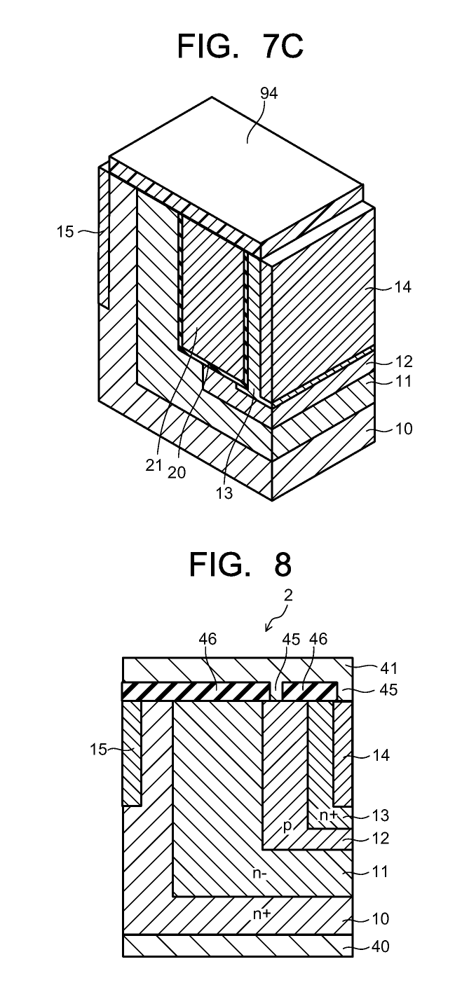

In the case of forming the metal layer 14 and the metal layer 15 in the separate steps, it is unnecessary to uniform the lengths in the depth direction of the metal layer 14 and the metal layer 15. As with the semiconductor element 1 according to the first embodiment, the gate electrode 21 may be formed after the metal layer 14 and the metal layer 15 are formed. The drain electrode 40 may be formed on the rear surface side of the semiconductor element 2 as illustrated in FIG. 8.

### Third Embodiment

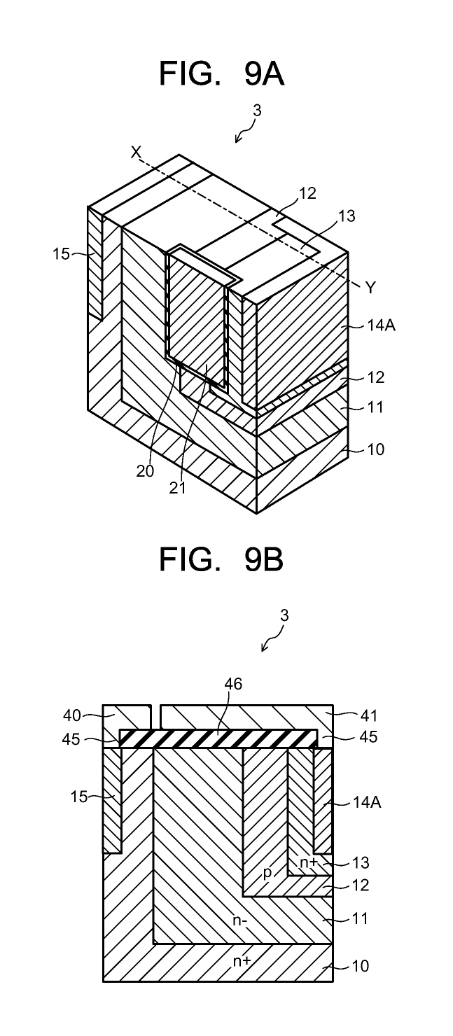

FIGS. 9A and 9B are schematic views of a principal part of a semiconductor element 3 according to a third embodiment. FIG. 9A is a schematic perspective view of the principal part of the semiconductor element 3. FIG. 9B is a schematic sectional view at an X-Y position in FIG. 9A. Hereinafter, the structure of the semiconductor element 3 according to the third embodiment will be described with reference to FIGS. 9A and 9B. The same configurations as those described in FIGS. 2A to 7C are given the same numerals and overlapping description will be omitted. In FIG. 9A, illustration of a drain electrode 40 and a source electrode 41 are omitted.

### (Structure of Semiconductor Element 3)

The semiconductor element 3 is a three-dimensional MOSFET. In the semiconductor element 3, as illustrated in FIGS. 9A and 9B, a metal layer 14A selectively formed from the front surface to the inside of a source region 13 extends to a part of a base region 12. Therefore, the source region 13 and the base region 12 are electrically connected so that the base region 12 can be fixed to the same potential as that of the source region 13. As a result, it becomes unnecessary to provide a via electrode on the front surface of the base region 12 as illustrated in FIG. 9B. The other structure is the same as that of the semiconductor element 2 described referring to FIGS. 6A and 6B.

### (Manufacturing Process of Semiconductor Element 3)

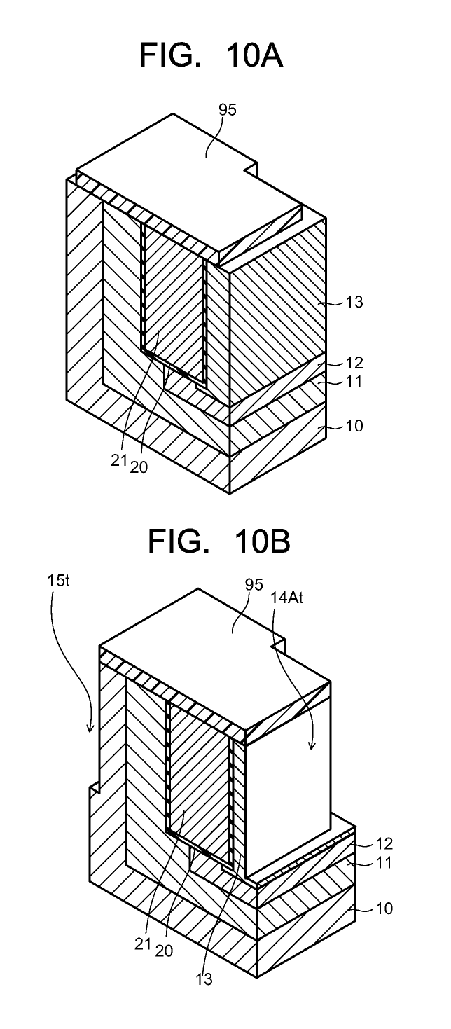

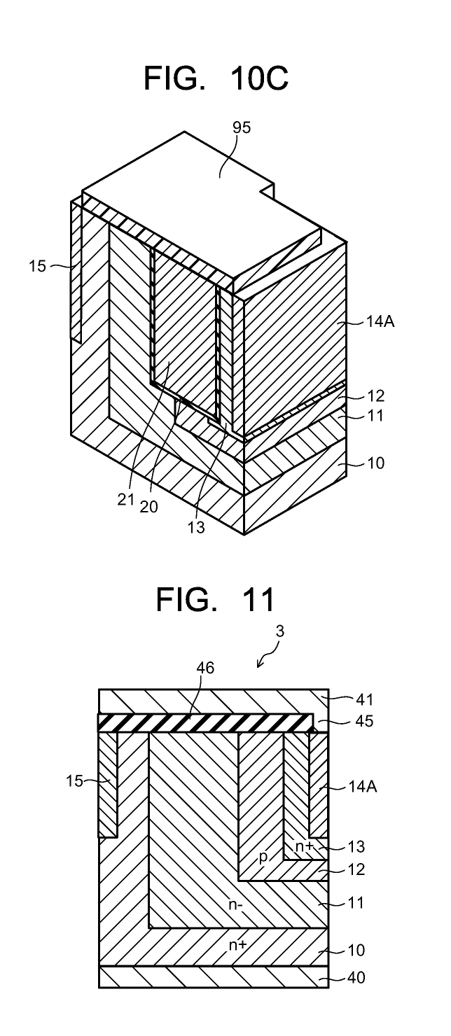

FIGS. 10A to 10C are explanatory views of the manufacturing process of the semiconductor element 3 according to the third embodiment. Hereinafter, the manufacturing process of the semiconductor element 3 will be described with reference to FIGS. 10A to 10C. The manufacturing process is the same as the manufacturing process of the semiconductor element 1 until the step of forming the gate electrode 21 described referring to FIG. 4F. Therefore, the manufacturing process after the gate electrode 21 is formed will be described in the third embodiment 3. The same configurations as those described in FIGS. 2A to 7C are given the same numerals and overlapping description will be omitted.

### (Mask Forming Step: see FIG. 10A)

As illustrated in FIG. 10A, a mask 95 is selectively formed so that parts of the front surfaces of the source region 13, the base region 12 and the drain layer 10 are exposed. The material of the mask 95 is, for example, silicon oxide (SiO₂).

### (Trench Forming Step: see FIG. 10B)

As illustrated in FIG. 10B, parts of the source region 13, the base region 12 and the drain layer 10 opened in the mask 95 are selectively etched. As a result, a trench 14At and a trench 15t are formed in the parts of the source region 13 and the base region 12 and the drain layer 10 respectively.

### (Metal Layer Forming Step: see FIG. 10C)

In the trench 14At and the trench 15t, a metal layer 14A and a metal layer 15 are formed. As a result, the metal layer 14A in the trench shape is formed from the front surfaces to the insides of parts of the source region 13 and the base region 12, and the metal layer 15 is selectively formed from the front surface to the inside of a part of the drain layer 10. The metal layer 14A and the metal layer 15 are preferably formed using W-CVD (tungsten CVD) because it provides excellent embedding property and requires no barrier metal and so on. However, the formation of the metal layer 14A and the metal layer 15 is not limited to W-CVD. Al-CVD or PVD may be used, for instance, as long as the embedding property is ensured. After the formation of the metal layer 14A and the metal layer 15, the mask 95 is removed.

As illustrated in FIG. 11, an interlayer insulating film 46 is formed on the drain layer 10, the drift region 11, the base region 12, the source region 13, the metal layer 14A and the metal layer 15. Then, a metal material such as tungsten (W) or the like is filled in a via hole formed in the interlayer insulating film 46 to form a via electrode 45. Thereafter, the drain electrode 40 and the source electrode 41 are formed on the interlayer insulating film 46 and the via electrode 45.

In the semiconductor element 3 according to the third embodiment, the metal layer 14A in the source region 13 is formed to extend to the base region 12 as described above. Therefore, the source region 13 and the base region 12 are electrically connected. By electrically connecting the source region 13 and the base region 12 as described above, the base region 12 can be fixed to the same potential as that of the source region 13.

In this case, it is unnecessary to connect the drain electrode 40 to any of the base region 12 and the source region 13, so that the constraint of the layout of the drain electrode 40 can be reduced. The other effects are the same as those of the semiconductor elements 1, 2 of the first and second embodiments.

As with the semiconductor element 1 according to the first embodiment, the gate electrode 21 may be formed after the metal layer 14A and the metal layer 15 are formed. The drain electrode 40 may be formed on the rear surface side of the semiconductor element 3 as illustrated in FIG. 11.

### Fourth Embodiment

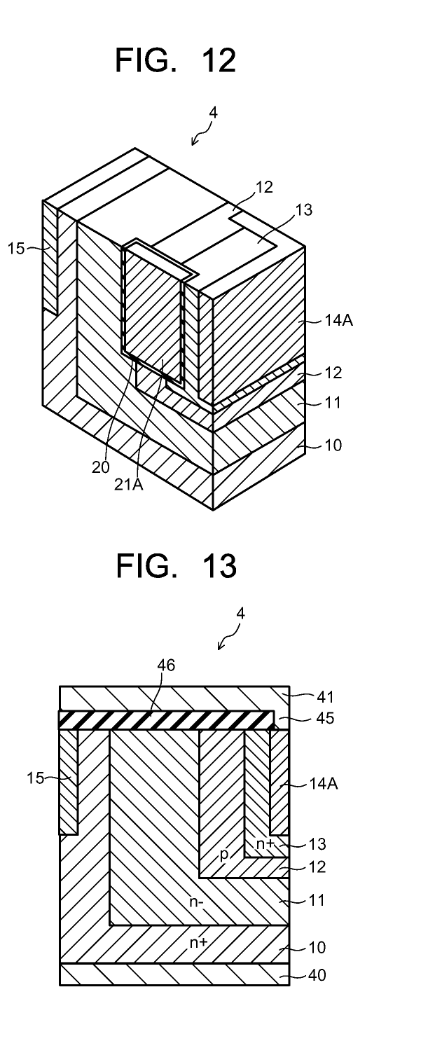

FIG. 12 is a schematic perspective view of a principal part of a semiconductor element 4 according to a fourth embodiment. Hereinafter, the structure of the semiconductor element 4 according to the fourth embodiment will be described with reference to FIG. 12. The same configurations as those described in FIGS. 2A to 10C are given the same numerals and overlapping description will be omitted. In FIG. 12, illustration of a drain electrode 40 and a source electrode 41 are omitted.

### (Structure of Semiconductor Element 4)

The semiconductor element 4 is a three-dimensional MOSFET. The semiconductor element 4 according to the fourth embodiment includes a gate electrode 21A made of a metal material (for example, tungsten (W)) as illustrated in FIG. 12. The gate electrode 21A is formed of a metal material with a low electric resistance and thereby can be reduced in gate resistance. As a result, the switching speed of the semiconductor element 4 can be improved.

### (Manufacturing Process of Semiconductor Element 4)

The manufacturing process of the semiconductor element 4 will be described. The difference between the semiconductor element 3 according to the third embodiment and the semiconductor element 4 according to the fourth embodiment is only the difference in material of the gate electrode (poly-silicon (Poly-Si) and metal). Therefore, only the manufacturing process of the gate electrode 21A will be described in this fourth embodiment, while overlapping description will be omitted. The same configurations as those described in FIGS. 2A to 10C are given the same numerals and overlapping description will be omitted.

As has been described referring to FIG. 4E, parts of the drift region 11, the base region 12 and the source region 13 opened in the mask 92 are selectively etched to form a trench 20t.

The inside of the trench 20t is exposed to an oxidizing atmosphere under a high temperature, whereby a gate insulating film 20 is formed at the side surface and the bottom surface of the trench 20t. Then, the gate electrode 21A is formed in the trench 20t via the gate insulating film 20. The gate electrode 21A is preferably formed using W-CVD (tungsten CVD) because it provides excellent embedding property and requires no barrier metal and so on. However, the formation of the gate electrode 21A is not limited to W-CVD. Al-CVD or PVD may be used, for instance, as long as the embedding property is ensured.

In the semiconductor element 4 according to the fourth embodiment, the gate electrode 21A is formed of a metal material with an electric resistance lower than that of poly-silicon as described above and thereby can be reduced in gate resistance. As a result, the switching speed of the semiconductor element 4 can be improved. The other effects are the same as those of the semiconductor elements 1 to 3 according to the first to third embodiments. The drain electrode 40 may be formed on the rear surface side of the drain layer 10 as illustrated in FIG. 13.

### Fifth Embodiment

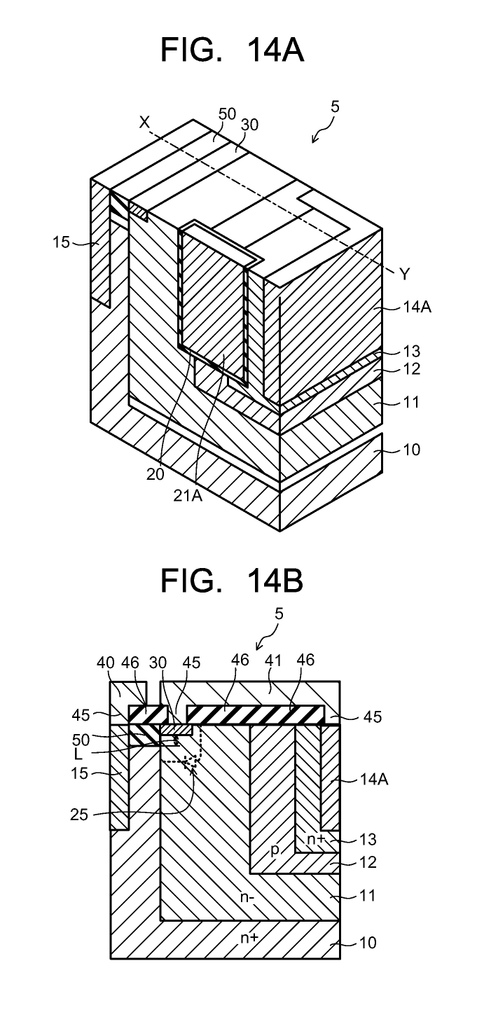

FIGS. 14A and 14B are schematic views of a principal part of a semiconductor element 5 according to a fifth embodiment. FIG. 14A is a schematic perspective view of the principal part of the semiconductor element 5. FIG. 14B is a schematic sectional view at an X-Y position in FIG. 14A. Hereinafter, the structure of the semiconductor element 5 according to the fifth embodiment will be described with reference to FIGS. 14A and 14B. The same configurations as those described in FIGS. 2A to FIG. 13 are given the same numerals and overlapping description will be omitted. In FIG. 14A, illustration of a drain electrode 40 and a source electrode 41 are omitted.

### (Structure of Semiconductor Element 5)

The semiconductor element 5 is a three-dimensional MOSFET. As illustrated in FIGS. 14A and 14B, an insulating layer 50 is provided on a drain layer 10 in the semiconductor element 5. Further, a p⁺-type (second conduction type) contact region 30 is selectively provided immediately adjacent to the insulating layer 50 and along the longitudinal direction of the insulating layer 50 on the surface of a drift region 11 in the semiconductor element 5. The contact region 30 is adjacent to a base region 12. The impurity concentration of the contact region 30 is higher than the impurity concentration of the base region 12. The contact region 30 is a carrier extraction region from which carriers (for example, holes) generated in the semiconductor device 100 can be extracted to the source region 41.

As illustrated in FIGS. 14A and 14B, the p⁺-type contact region 30 is arranged at a position of a distance L near the n⁺-type drain layer 10 via the n⁻-type drift region 11 in the semiconductor element 5. In other words, a pn diode 25 with the contact region 30 as the p-side and the drain layer 10 as the n-side is formed at the position of the distance L from the drain layer 10 between the source electrode 41 and the drain electrode 40.

### (Manufacturing Process of Semiconductor Element 5)

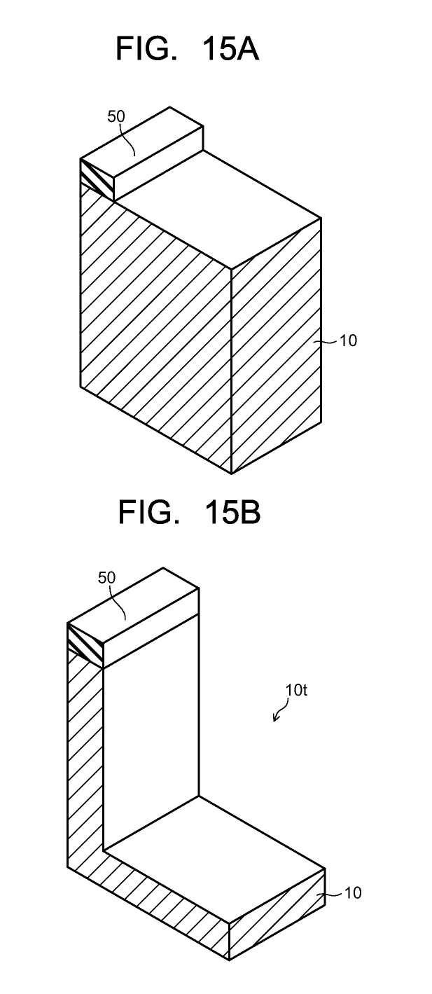

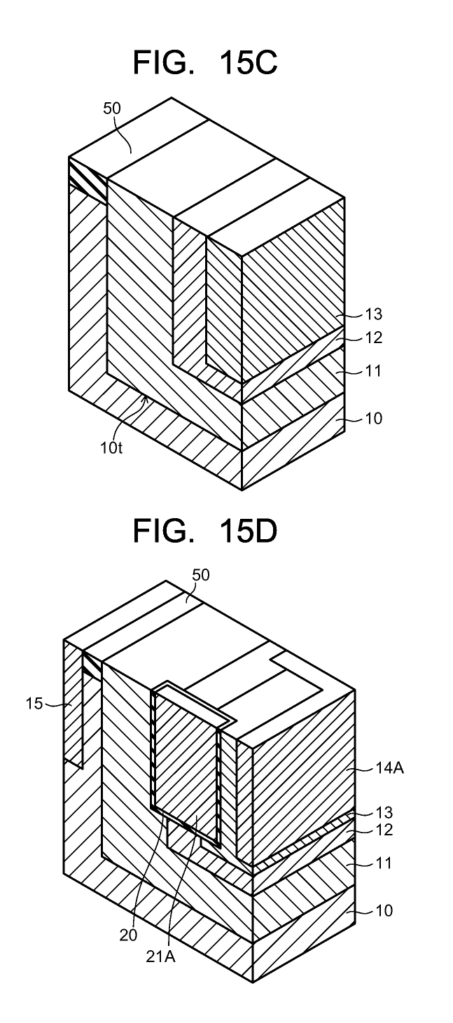

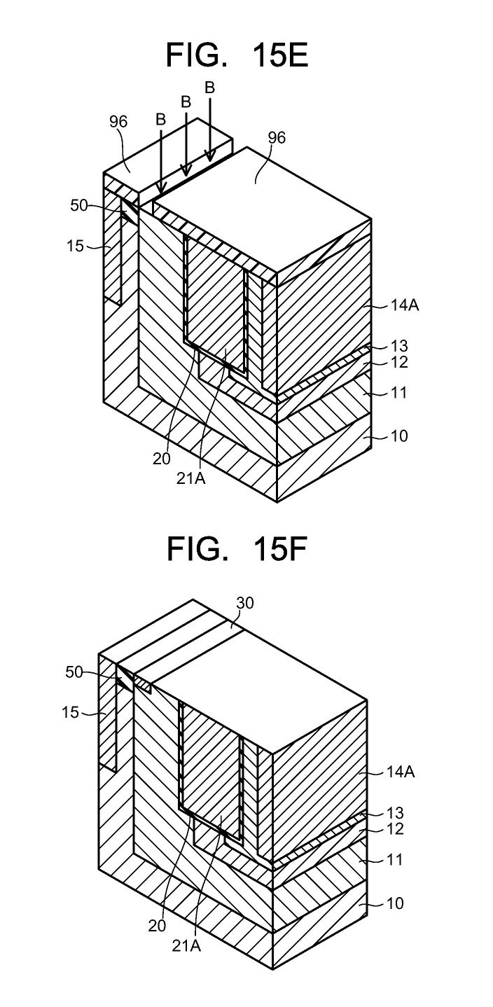

FIGS. 15A to 15F are explanatory views of the manufacturing process of the semiconductor element 5 according to the fifth embodiment. Hereinafter, the manufacturing process of the semiconductor element 5 will be described with reference to FIGS. 15A to 15F. The same configurations as those described in FIGS. 2A to 12 are given the same numerals and overlapping description will be omitted.

### (Insulating Layer Forming Step: see FIG. 15A)

The drain layer 10 that is a semiconductor substrate (semiconductor wafer) is prepared. The impurity concentration of the drain layer 10 is, for example, 1×10¹⁸ atoms/cm³ or higher. Subsequently, the insulating layer 50 is selectively formed so that a part of the front surface of drain layer 10 is exposed. The material of the insulating layer 50 is, for example, silicon oxide (SiO₂).

### (Etching Step: see FIG. 15B)

As illustrated in FIG. 15B, the drain layer 10 opened in the insulating layer 50 is selectively etched. As a result, a trench 10t is formed from the front surface to the inside of the drain layer 10.

### (Drift Region 11 Forming Step: see FIG. 15C)

Inside the trench 10t, the n-type drift region 11 is formed by the epitaxial growth method. As a result, the drift region 11 is formed from the front surface to the inside of the drain layer 10. The impurity concentration of the drift region 11 is, for example, 1×10¹² atoms/cm³ to 1×10¹³ atoms/cm³.

The formation of the drift region 11 is interrupted in the middle, and the p-type base region 12 is formed in the trench 10t left in the drift region 11 by the epitaxial growth method. As a result, the base region 12 is formed from the front surface to the inside of the drift region 11.

The formation of the base region 12 is interrupted in the middle, and the n⁺-type source region 13 is formed in the trench 10t left in the base region 12 by the epitaxial growth method. As a result, the source region 13 is selectively formed from the front surface to the inside of the base region 12.

The front surfaces of the drift region 11, the base region 12 and the source region 13 are polished by CMP (Chemical Mechanical Polishing). The front surfaces of the drift region 11, the base region 12 and the source region 13 are subjected to the CMP polishing to be at the same height as the front surface of the insulating layer 50.

### (Forming Steps of Gate Electrode 21A and Metal Layers 14A, 15: see FIG. 15D)

As illustrated in FIG. 15D, a gate electrode 21A, a metal layer 14A and a metal layer 15 are formed. The forming steps of the metal electrode 14A and the metal electrode 15 have been described referring to FIGS. 10A to 10C. The forming step of the gate electrode 21A has been described referring to FIG. 12. Therefore, overlapping description of the forming steps of the gate electrode 21A, the metal layer 14A and the metal layer 15 will be omitted.

### (Mask Forming Step: see FIG. 15E)

As illustrated in FIG. 15E, a mask 96 is selectively formed so that a part of the front surface of the drift region 11 is exposed. The material of the mask 96 is, for example, silicon oxide (SiO₂).

### (Contact Region Forming Step: see FIG. 15F)

A p-type impurity (for example, born (B)) is ion-implanted to the drift region 11 whose front surface is exposed and heat treatment is performed. As a result, the contact region 30 extending along the longitudinal direction of the insulating layer 50 is formed immediately adjacent to the insulating layer 50 as illustrated in FIG. 15C-b. After the ion-implantation, the mask 96 is removed.

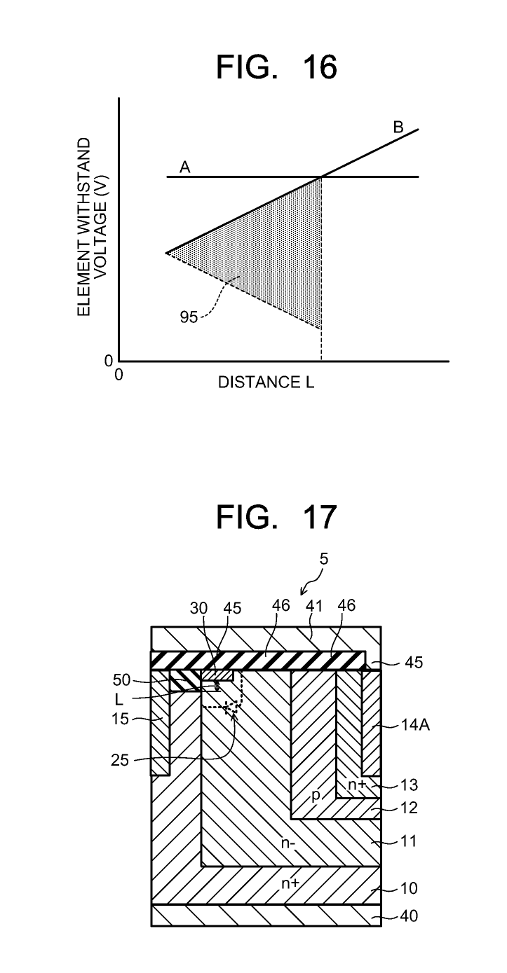

FIG. 16 is a graph representing the relation between the distance L (the distance between the contact region 30 and the drain layer 10) and the withstand voltage of the semiconductor element. The horizontal axis in FIG. 16 is the distance L. The vertical axis in FIG. 16 is the element withstand voltage (V) of the semiconductor element 5.

The element withstand voltage of the source region 13/the base region 12/the drift region 11 does not depend on the distance L. Therefore, the value of the element withstand voltage (V) is constant with respect to the distance L as illustrated by the line A in FIG. 16. Meanwhile, when there is a pn diode 25, holes are more likely to occur near the pn diode 25 as the distance L becomes smaller. Therefore, the Zener breakdown due to the pn diode 25 increases. As a result, the element withstand voltage (V) decreases as the distance L becomes smaller as illustrated by the line B in FIG. 16.

In the semiconductor element 5, adjusting the distance L makes it possible to cause the avalanche breakdown near the pn diode 25 before the avalanche breakdown occurs near the lower end of the gate electrode 21A or at the joint interface between the base region 12 and the drift region 11. In other words, adjusting the distance L ensures that the place where holes are generated due to the avalanche breakdown is not near the lower end of the gate electrode 21 or at the joint interface between the base region 12 and the drift region 11 but near the pn diode 25 in the semiconductor element 5.

The holes generated near the pn diode 25 are quickly discharged to the source electrode 41 side through the contact region 30 provided near the pn diode 25. In the semiconductor element 5, the pn diode 25 is formed outside the base region 12. Therefore, the semiconductor element 5 is configured such that the holes generated near the pn diode 25 hardly flow into the base region 12. As a result, the holes generated due to the avalanche breakdown hardly flow into the base region 12, so that the bipolar action due to a parasitic bipolar transistor is restricted, resulting in improved element withstand voltage of the semiconductor element 5.

As described above, the pn diode 25 with the contact region 30 as the p side and the drain layer 10 as the n side is formed between the source electrode 41 and the drain electrode 40 in the semiconductor element 5 according to the fifth embodiment. As a result, the element withstand voltage of the semiconductor element 5 is improved. Further, the contact region 30 is formed immediately adjacent to the insulating layer 50 and along the longitudinal direction of the insulating layer 50. As a result, exposure alignment when forming the mask 96 becomes easy to perform. The other effects are the same as those of the semiconductor elements 1 to 4 according to the first to fourth embodiments. The drain electrode 40 may be formed on the rear surface side of the drain layer 10 as illustrated in FIG. 17.

### Modified Examples of Fifth Embodiment

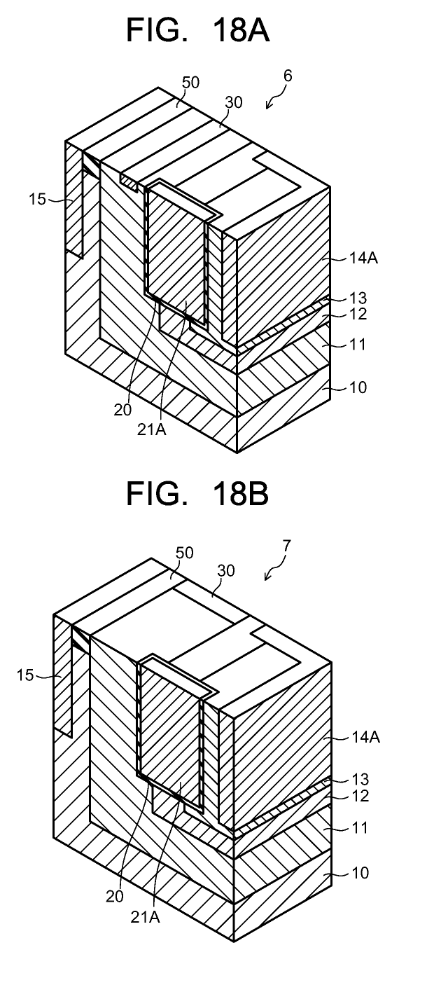

FIGS. 18A and 18B are schematic views of principal parts of semiconductor elements 6, 7 according to modified examples of the fifth embodiment. In the semiconductor element 5 according to the fifth embodiment, the p⁺-type contact region 30 is formed to extend immediately adjacent to the insulating layer 50 and along the longitudinal direction of the insulating layer 50. However, the position where the contact region 30 is formed is not limited to the position illustrated in FIGS. 14A and 14B.

For example, the contact region 30 may be formed to extend along the longitudinal direction of the insulating layer 50 at the position distant from the insulating layer 50 as illustrated in FIG. 18A. Alternatively, the contact region 30 may be formed in a direction substantially perpendicular to the longitudinal direction of the insulating layer 50 as illustrated in FIG. 18B. Even when the contact region 30 is formed at the position illustrated in FIG. 18A or FIG. 18B, the element withstand voltage of the semiconductor element 6, 7 is improved because the pn diode with the contact region 30 as the p side and the drain layer 10 as the n side is formed. The other effects are the same as those of the semiconductor elements 1 to 4 according to the first to fourth embodiments. When the contact region 30 is formed at the position illustrated in FIG. 18A, the insulating layer 50 may be omitted.

While certain embodiments have been described, these embodiments have been presented by way of example only, and are not intended to limit the scope of the inventions. Indeed, the novel embodiment described herein may be embodiment in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

For example, the gate electrodes 20 of each of the semiconductor elements 1 to 3 according to the first to third embodiments may be replaced with the gate electrode 21A of the semiconductor element 4 according to the fourth embodiment. The gate electrode 21A of the semiconductor element 5 according to the fifth embodiment may be replaced with the gate electrode 20 of each of the semiconductor elements 1 to 3 according to the first to third embodiments.

The metal layer 14 of the semiconductor element 2 according to the second embodiment may be omitted. The metal layer 15 of the semiconductor element 3 according to the third embodiment may be omitted.

The metal layer 14A of the semiconductor element 4 according to the fourth embodiment may be replaced with the metal layer 14 of the semiconductor element 1 according to the first embodiment 1. The metal layer 14A of the semiconductor element 4 according to the fourth embodiment may be omitted. The metal layer 15 of the semiconductor element 4 according to the fourth embodiment may be omitted.

The metal layer 14A of the semiconductor element 5 according to the fifth embodiment may be replaced with the metal layer 14 of the semiconductor element 1 according to the first embodiment. The metal layer 14A of the semiconductor element 5 according to the fifth embodiment may be omitted. The metal layer 15 of the semiconductor element 5 according to the fifth embodiment may be omitted.

The contact region 30 may be formed in the semiconductor elements 1 to 4 according to the first to fourth embodiments. Though the n-type MOSFET has been described as an example in each of the above-described embodiments, a p-type MOSFET may be employed. In this case, the drain layer 10, the drift region 11 and the source region 13 are of the p-type (second conduction type), and the base region 12 and the contact region 30 are of the n-type (first conduction type).

What is claimed is:

1. A semiconductor element, comprising:
a drain layer having a front surface and a rear surface;
a drift region selectively provided in the drain layer from the front surface to an inside of the drain layer;
a base region selectively provided in the drift region from a front surface to an inside of the drift region;
a source region selectively provided in the base region from a front surface to an inside of the base region;
first and/or second metal layers selectively provided in at least one of the source region and the drain layer from the front surface to the inside of at least one of the source region and the drain layer;
a gate electrode in a trench shape extending in a direction substantially parallel to the front surface of the drain layer from a part of the source region through the base region adjacent to at least the part of the source region to a part of the drift region;
a source electrode connected to the first metal layer; and
a drain electrode connected to the drain layer or the second metal layer.

2. The element according to claim 1,
wherein the first metal layer extends to at least a part of the base region.

3. The element according to claim 1,
wherein the gate electrode is made of a metal material.

4. The element according to claim 1, further comprising a contact region selectively provided on the front surface of the drift region and at a position distant from the front surface of the drain layer and containing an impurity at a concentration higher than an impurity concentration of the base region.

5. The element according to claim 4, further comprising an insulating layer provided in the drain layer from the front surface to the inside of the drain layer.

6. The element according to claim 5,
wherein a plane including a rear surface of the contact region and a plane including a rear surface of the insulating layer are distant in a direction vertical to the front surface of the drift region.

7. The element according to claim 1,
wherein the drain layer, the drift region and the source region are of a first conduction type, and the base region is of a second conduction type.

8. The element according to claim 4,
wherein the drain layer, the drift region and the source region are of a first conduction type, and the base region and the contact region are of a second conduction type.

9. The element according to claim 1,
wherein the drain layer, the drift region and the source region are of a second conduction type, and the base region is of a first conduction type.

10. The element according to claim 4,
wherein the drain layer, the drift region and the source region are of a second conduction type, and the base region and the contact region are of a first conduction type.

11. A method of manufacturing a semiconductor element, comprising:
selectively forming a first trench in a drain layer having a front surface and a rear surface, from the front surface of the drain layer in a direction vertical to the front surface;
forming a drift region, a base region and a source region in the first trench in an order of the drift region, the base region and the source region;
forming a second trench extending in a direction substantially parallel to the front surface of the drain layer from a part of the source region through the base region adjacent to at least the part of the source region to a part of the drift region;
forming a gate insulating film in the second trench;
forming a gate electrode on a front surface of the gate insulating film;
selectively forming third and/or fourth trenches on a front surface of at least one of the source region and the drain layer from the front surface to an inside of at least one of the source region and the drain layer;
forming first and/or second metal layers in at least one of the third and fourth trenches;
forming a source electrode electrically connected to the first metal layer; and
forming a drain electrode electrically connected to the drain layer or the second metal layer.

12. The method according to claim 11,
wherein the third trench is selectively formed on front surfaces of the source region and the base region from the front surfaces to insides of the source region and the base region.

13. The method according to claim 11,
wherein the third and fourth trenches are formed in a same step.

14. The method according to claim 11,
wherein the first and second metal layers are formed in a same step.

15. The method according to claim 11, further comprising selectively doping an impurity to the front surface of the drift region and at a position distant from the front surface of the drain layer to form a contact region containing an impurity at a concentration higher than an impurity concentration of the base region.

16. The method according to claim 15, further comprising selectively forming an insulating film on the front surface of the drain layer before the first trench is formed,
wherein the first trench is formed in a region other than a region where the insulating film is formed.
